(19) United States
(12) Patent Application Publication
(10) Pub. No.: US 2025/0218952 A1
(43) Pub. Date: Jul. 3, 2025

(54) SPACER FOR EMBEDDED COMPONENT IN CORE

(71) Applicant: Intel Corporation, Santa Clara, CA (US)

(72) Inventors: Benjamin DUONG, Phoenix, AZ (US); Tolga ACIKALIN, San Jose, CA (US); Soham AGARWAL, Chandler, AZ (US); Jeremy D. ECTON, Gilbert, AZ (US); Kari HERNANDEZ, Phoenix, AZ (US); Brandon C. MARIN, Gilbert, AZ (US); Pratyush MISHRA, Tempe, AZ (US); Pratyasha MOHAPATRA, Hillsboro, OR (US); Srinivas Venkata Ramanuja PIETAMBARAM, Chandler, AZ (US); Marcel SAID, Beaverton, OR (US); Bohan SHAN, Chandler, AZ (US); Gang DUAN, Chandler, AZ (US)

(21) Appl. No.: 18/398,715

(22) Filed: Dec. 28, 2023

(51) Int. Cl. H01L 23/538; H01L 23/00

(52) U.S. Cl. CPC H01L 23/5381; H01L 24/05; H01L 24/13; H10D 1/68; H01L 2224/05009; H01L 2224/05025; H01L 2224/13009; H01L 2224/13025; H01L 2924/01029; H01L 2924/1205; H01L 2924/1431

(57) ABSTRACT

Embodiments disclosed herein include components that are embedded within a core of a package substrate. In an embodiment, such an apparatus may comprise a substrate with a first surface and a second surface opposite from the first surface. In an embodiment, a cavity is provided through a thickness of the substrate, and a first layer is in the cavity. In an embodiment, the first layer has a first width. In an embodiment, a component is on the first layer, and the component has a second width that is smaller than the first width. In an embodiment, a second layer is provided between a sidewall of the cavity and a sidewall of the component.

### BACKGROUND

As advanced packaging is enabling more aggressive computation capability, high power and high quality power delivery is needed to support all of the overlying chiplets. The ability to embed passive components (e.g., capacitors, inductors, resistors, etc.) into the package substrate will enable improved performance compared to placing the passive components on the land side of the package. Embedding components in the core is beneficial because there is less routing in the core compared to overlying and underlying buildup layers. As such, space within the package substrate is more fully utilized.

However, substrate core thickness is defined by the total package thermomechanical stress level. This required thickness can be significantly different than—the thickness of the passive component. For example, in the case of a deep trench capacitor (DTC), the DTC is fabricated on a silicon wafer. The wafer will have a thickness that is potentially hundreds of microns different than the thickness of the core, which can be approximately 1.0 mm or greater. Placing such passive components in deep cavities through the core can be problematic. For example, the passive components may shift or rotate during embedding.

### BRIEF DESCRIPTION OF THE DRAWINGS

FIG. 1 is a cross-sectional illustration of a core with an embedded passive component that has shifted during the embedding process, in accordance with an embodiment.

FIG. 2A is a cross-sectional illustration of a portion of a package substrate that comprises a component on a spacer layer embedded in a core, in accordance with an embodiment.

FIG. 2B is a cross-sectional illustration of a portion of a package substrate that comprises a component on a spacer layer with vertical arms embedded in a core, in accordance with an embodiment.

FIG. 2C is a cross-sectional illustration of a portion of a package substrate that comprises a component on a spacer layer and a liner embedded in a core, in accordance with an embodiment.

FIG. 2D is a cross-sectional illustration of a portion of a package substrate that comprises a component on a spacer layer with arms and a liner embedded in a core, in accordance with an embodiment.

FIGS. 3A-3G are cross-sectional illustrations depicting a process for forming a package substrate with a component embedded in a core of the package substrate, in accordance with an embodiment.

FIG. 3H is a process flow diagram of a process for embedding a component in a core, in accordance with an embodiment.

FIGS. 4A-4F are cross-sectional illustrations depicting a process for forming a package substrate with a component embedded in a core of the package substrate, in accordance with an additional embodiment.

FIG. 4G is a process flow diagram of a process for embedding a component in a core, in accordance with an embodiment.

FIG. 5 is a cross-sectional illustration of a portion of a package substrate that comprises a plurality of cavities with components with different thicknesses over a spacer layer, in accordance with an embodiment.

FIG. 6 is a cross-sectional illustration of a portion of a package substrate that comprises a plurality of cavities with components with different thicknesses over a spacer layer and a liner, in accordance with an embodiment.

FIG. 7 is a cross-sectional illustration of an electronic system that comprises a package substrate with a component embedded in a core of the package substrate, in accordance with an embodiment.

FIG. 8 is a schematic of a computing device built in accordance with an embodiment.

### EMBODIMENTS OF THE PRESENT DISCLOSURE

Described herein are electronic systems, and more particularly, cavities in package substrate cores that have spacer layers for supporting thin components in the cavities, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

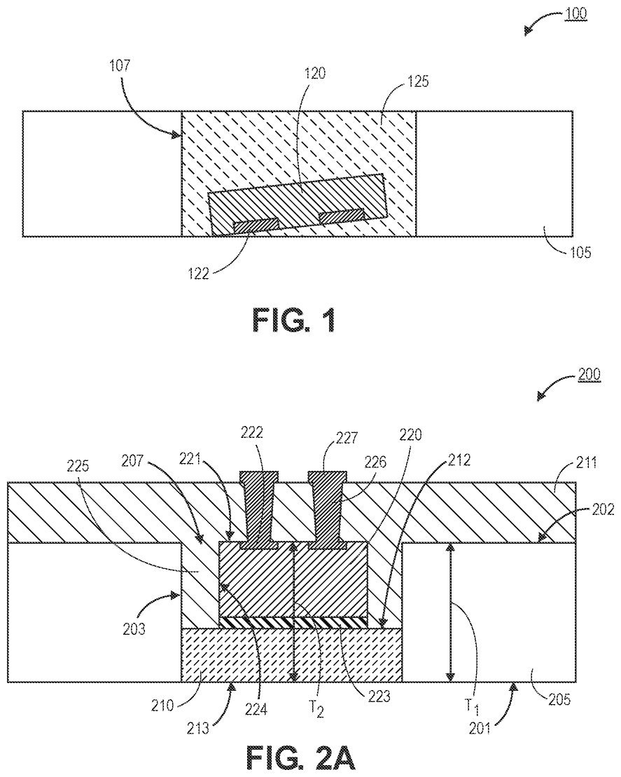

As noted above, introducing passive components (e.g., inductors, capacitors, resistors, etc.) into the package substrate is desirable to improve power delivery and performance for the overlying chiplets compared to placing the passive components on the land side of the package substrate. This is due, at least in part, to the passive components being physically closer to the chiplets when they are integrated into the package substrate. One suitable location in the package substrate for the passive components is the core. The core has underutilized space that can be leveraged to house the passive components. However, the thickness of the passive components is usually smaller than a thickness of the core. This can lead to integration and manufacturing issues. Examples of these drawbacks can be seen in FIG. 1.

Referring now to FIG. 1, a cross-sectional illustration of a portion of a package substrate 100 is shown, in accordance with an embodiment. The package substrate 100 may comprise a core 105. The core 105 may sometimes be referred to simply as a substrate. The core 105 may be a glass core, an organic core, a silicon core, or the like. In an embodiment, a cavity 107 passes at least partially through the core 105. For example, in FIG. 1 the cavity 107 passes entirely through the core 105.

In an embodiment, a component 120 is provided in the cavity 107. The component 120 may have a thickness that is smaller than a thickness of the core 105. For example, the component 120 may have a thickness that is hundreds of microns thinner than the core 105. The component 120 is secured within the cavity 107 through the use of a fill layer 125. The fill layer 125 may be a dielectric material, such as a mold layer, an epoxy, an adhesive, or the like. However, during the filling process, the component 120 may shift and/or rotate. The movement of the component 120 may be due, at least in part, to the introduction of pressure to the component 120 during the filling process. As shown, the component 120 has tilted so that one side is raised up from the bottom of the core 105. This may make it difficult to make electrical contact to the pads 122 that are at the bottom of the component 120 in subsequent processing operations.

Accordingly, embodiments disclosed herein reduce movement of the electrically passive component by supporting the component on a spacer layer. This raises the component up towards the top surface of the core. As such, a thickness mismatch between a thickness of the core and a thickness of the component is reduced or eliminated. Subsequent embedding is made easier, and is less likely to displace the component. Additionally, vias to the component may be shorter and easier to fabricate.

In some embodiments, the spacer layer is a dielectric layer. The spacer layer may have a planar top surface across an entire width of the cavity. For example, the spacer layer may be deposited so that the spacer layer full fills the cavity, and the top surface of the spacer layer can then be recessed (e.g., with an etching process). In other embodiments, the spacer layer may comprise arms that extend up to a top surface of the core. That is, only a portion of the top surface of the spacer layer is recessed in some embodiments.

Embodiments may also include a liner within the cavity. The liner may be provided over the top surface of the spacer layer and along sidewalls of the cavity. The liner may comprise a metallic material, such as a copper. When a plating process is used to deposit the liner, the thickness of the liner can be precisely controlled. This allows for improved thickness matching with the core.

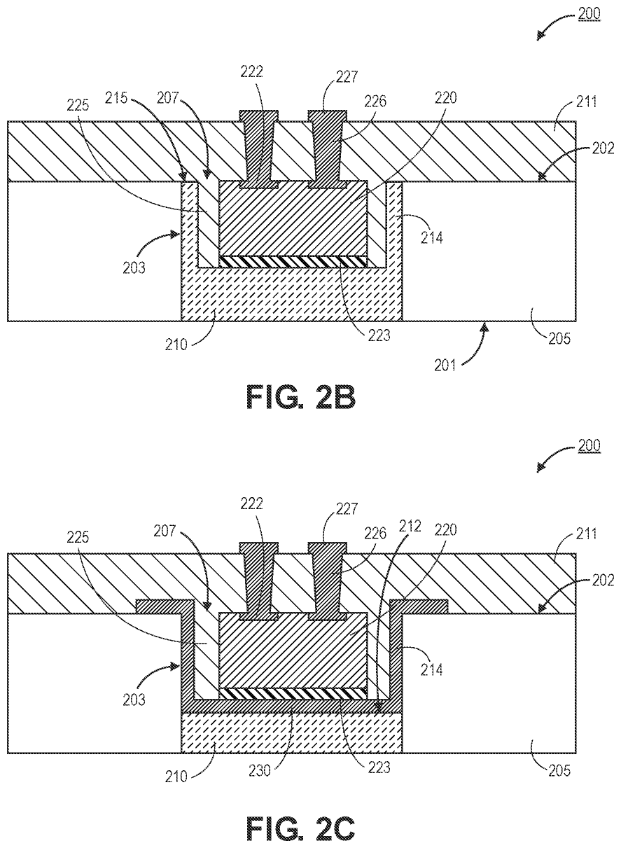

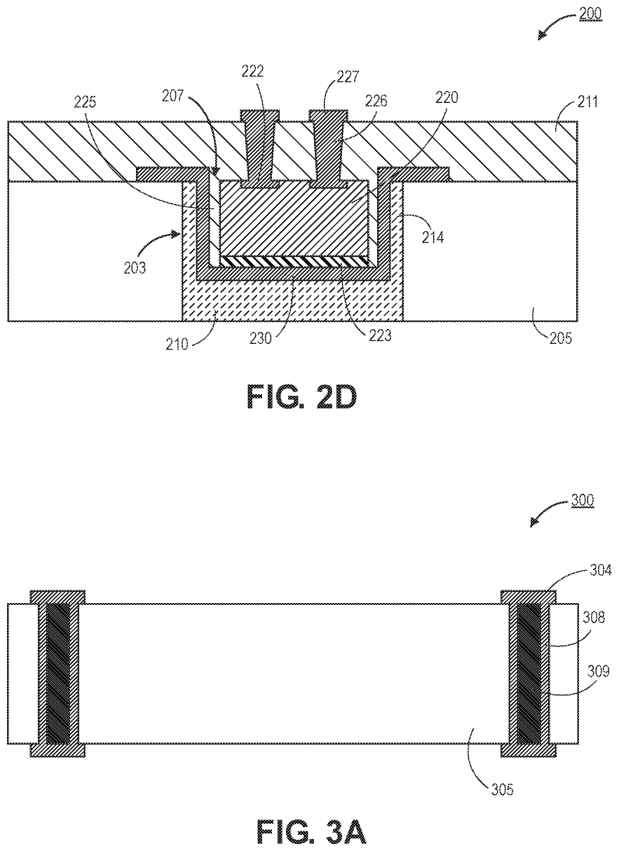

Referring now to FIG. 2A, a cross-sectional illustration of a portion of a package substrate 200 is shown, in accordance with an embodiment. In an embodiment, the package substrate 200 may comprise a core 205. The core 205 may be an organic core 205 or a glass core 205. In the case of a glass core 205, the glass core 205 may be substantially all glass. The glass core 205 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 205 may be distinguished from, for example, the “prepreg” or “FR4” core of a Printed Circuit Board (PCB) substrate which typically comprises glass fibers embedded in a resinous organic material, such as an epoxy.

The glass core 205 may have any suitable dimensions. In a particular embodiment, the glass core 205 may have a thickness that is approximately 50 μm or greater. For example, the thickness of the glass core 205 may be between approximately 50 μm and approximately 3 mm. Though, smaller or larger thicknesses may also be used. The glass core 205 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 205 (from an overhead plan view) may be between approximately 10 mm×10 mm and approximately 250 mm×250 mm. In an embodiment, the glass core 205 may have a first side that is perpendicular or orthogonal to a second side. In a more general embodiment, the glass core 205 may comprise a rectangular prism volume with sections (e.g., vias) removed and filled with other materials (e.g., metal, etc.).

The glass core 205 may comprise a single monolithic layer of glass. In other embodiments, the glass core 205 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 205 may each have a thickness less than approximately 50 μm. For example, discrete layers of glass in the glass core 205 may have thicknesses between approximately 25 μm and approximately 3 mm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 205 may be any suitable glass formulation that has the necessary mechanical robustness and compatibility with semiconductor packaging manufacturing and assembly processes. For example, the glass core 205 may comprise aluminosilicate glass, borosilicate glass, alumino-borosilicate glass, silica, fused silica, or the like. In some embodiments, the glass core 205 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 205 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 205 may comprise at least 23 percent silicon (by weight) and at least 26 percent oxygen (by weight). In some embodiments, the glass core 205 may further comprise at least 5 percent aluminum (by weight).

In an embodiment, a cavity 207 may be provided through a thickness of the core 205. The cavity 207 may have sidewalls 203. The sidewalls 203 may be substantially orthogonal to a first surface 201 and a second surface 202 of the core 205. As used herein, “substantially orthogonal” may refer to angles that are between 85° and 95°. While vertical sidewalls 203 are shown in FIG. 2A, it is to be appreciated that sloped or tapered sidewalls 203 may also be provided in some embodiments.

In an embodiment, a bottom portion of the cavity 207 may be filled by a spacer layer 210. The spacer layer 210 may have a first surface 213 that is substantially coplanar with the first surface 201 of the core 205. As used herein, “substantially coplanar” may refer to two surfaces that are within 5° of being parallel to each other and within 20 μm of being along the same plane. In an embodiment, the spacer layer 210 may have a second surface 212 that is substantially parallel to the first surface 201 of the core 205. As used herein, “substantially parallel” may refer to two surfaces, lines, etc. that are within 5° of being parallel to each other. In an embodiment, a width of the spacer layer 210 may be substantially equal to a width of the cavity 207. As used herein, “substantially equal” refers to two values that are within 10% of each other. For example, a range of 90 μm to 110 μm would be substantially equal to a value of 100 μm. In some instances, the spacer layer 210 may be considered as providing a seal to an opening (i.e., the bottom opening, as viewed in FIG. 2A) of the cavity 207. In an embodiment, the spacer layer 210 may comprise a dielectric material. For example, the spacer layer 210 may comprise an organic buildup film, a molding material, an epoxy, a photoimageable dielectric (PID), or the like.

In an embodiment, a component 220 may be provided in the cavity 207 over the spacer layer 210. In an embodiment, the component 220 may be an electrically passive structure or device. For example, the component 220 may comprise one or more of an inductor, a capacitor, or a resistor. In a particular embodiment, the component 220 may comprise a deep trench capacitor (DTC). The component 220 may include a substrate, such as a silicon substrate or other semiconductor substrate. Though, components 220 may also be fabricated on other materials, such as glass, ceramics, dielectrics, or the like.

In the Figures described herein, component 220 is shown as a simple layer. The electrical routing (e.g., traces, pads, plates, electrodes), insulators, dielectrics (e.g., high-k dielectrics for capacitors), magnetic material (e.g., for inductors), and/or the like are omitted for simplicity. However, it is to be appreciated that the component 220 may include any structures that enable functionality of various passive components. Though, pads 222 are illustrated on the component 220. The pads 220 may comprise copper or other suitable electrically conductive material. In the illustrated embodiment, the pads 222 are recessed into the top surface of the component 220. Other embodiments may include pads 222 that extend up from the top surface of the component 220. In an embodiment, vias 226 coupled to the pads 222 may pass through an overlying buildup layer 211 and connect to pads 227. Pads 227 may electrically couple the component 220 to other devices (e.g., dies) (not shown) that are on or coupled to the package substrate 200. In an embodiment, the component 220 may be coupled to the spacer 210 by an intervening layer 223. The intervening layer 223 may be an adhesive, such as a die bonding film (DBF).

In an embodiment, a width of the component 220 may be smaller than a width of the spacer layer 210. As such, sidewalls 224 of the component 220 are spaced away from the sidewalls 203 of the cavity 207. In an embodiment, a fill layer 225 may be provided between the sidewalls 224 of the component 220 and the sidewalls 203 of the cavity 207. The fill layer 225 may be the same material as the buildup layer 211. For example, the fill layer 225 and the buildup layer 211 may comprise organic dielectric material, such as buildup film or the like. Further, while shown as having different shadings, in some embodiments the spacer layer 210 and the fill layer 225 may comprise the same material or a similar material. As such, there may be no discernable boundary between the spacer layer 210 and the fill layer 225. In such an instance, the spacer layer 210 may be considered as being the material that is within the cavity 207 and below the component 220, and the fill layer 225 may be considered as being the material that is within the cavity 207 and surrounding sidewalls 224 of the component 220.

In an embodiment, the core 205 may have a first thickness T₁, and the combination of the spacer layer 210, the intervening layer 223, and the component 220 may have a second thickness T₂. That is, the second distance T₂ may be a distance between the bottom surface of the spacer layer 210 and a top surface 221 of the component 220. In an embodiment, the first thickness T₁ is substantially equal to the second thickness T₂. For example, the top surface 221 of the component 220 may be substantially coplanar with the second surface 202 of the core 205. Though, it is to be appreciated that in some embodiments the first thickness T₁ may be different (i.e., larger or smaller) than the second thickness T₂.

Referring now to FIG. 2B, a cross-sectional illustration of a portion of a package substrate 200 is shown, in accordance with an additional embodiment. In an embodiment, the package substrate 200 in FIG. 2B is similar to the package substrate 200 in FIG. 2A, with the exception of the structure of the spacer layer 210. In an embodiment, the spacer layer 210 in FIG. 2B includes arms 214 that extend up towards the second surface 202 of the core 205. The arms 214 may have a top surface 215 that is substantially coplanar with the second surface 202 of the core 205. As such, some portions of the spacer layer 210 may have a thickness that is substantially equal to a thickness of the core 205. The arms 214 may directly contact the sidewalls 203 of the cavity 207. In an embodiment, the fill layer 225 may be provided between the arms 214 and the component 220. Stated another way, the fill layer 225 and the arms 214 may be between the component 220 and the sidewalls 203 of the cavity 207.

Referring now to FIG. 2C, a cross-sectional illustration of a portion of a package substrate 200 is shown, in accordance with an embodiment. In an embodiment, the package substrate 200 in FIG. 2C may be similar to the package substrate 200 in FIG. 2A, with the addition of a liner 230 within the cavity 207. In an embodiment, the liner 230 contacts the sidewalls 203 of the cavity 207 and the second surface 212 of the spacer layer 210. In some embodiments, the liner 230 may also contact the second surface 202 of the core 205. In an embodiment, the liner 230 may be separated from the component 220 by the fill layer 225.

In an embodiment, the liner 230 may comprise a metallic material. For example, the liner 230 may comprise copper or the like. In an embodiment, the liner 230 may be plated with an electroplating process or the like. Accordingly, accurate thickness control of the liner 230 can be provided. This allows for the combined thickness of the spacer layer 210 and the liner 230 to be accurately controlled in order to properly position the component 220 within the cavity 207.

In some embodiments, the intervening layer 223 may comprise a solder material when a metallic liner 230 is used. In such an instance, the backside of the component 220 may be metallized in order to accommodate the solder. The use of a metallized component 220, solder, and the liner 230 may provide thermal regulation benefits since more thermal energy can be drawn from the component 220 and dissipated through the liner 230.

Referring now to FIG. 2D, a cross-sectional illustration of a portion of a package substrate 200 is shown, in accordance with an additional embodiment. In an embodiment, the package substrate 200 in FIG. 2D may be similar to the package substrate 200 in FIG. 2B, with the addition of a liner 230 (e.g., similar to liner 230 described with respect to FIG. 2C). For example, the liner 230 may be spaced away from the sidewalls 203 of the cavity 207 by the arms 214. In some embodiments, the sidewalls 203 of the cavity 207 may be spaced away from the component 220 by the arms 214, the liner 230, and the fill layer 225.

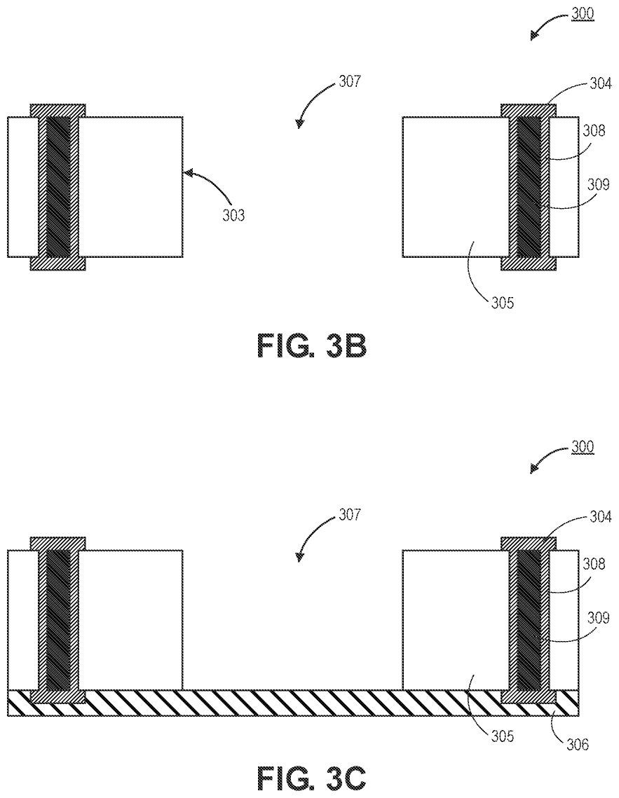

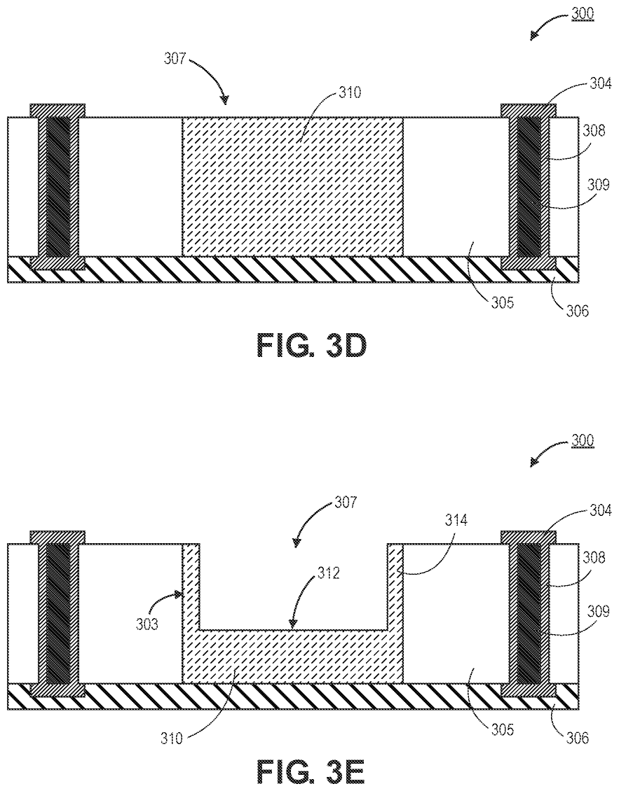

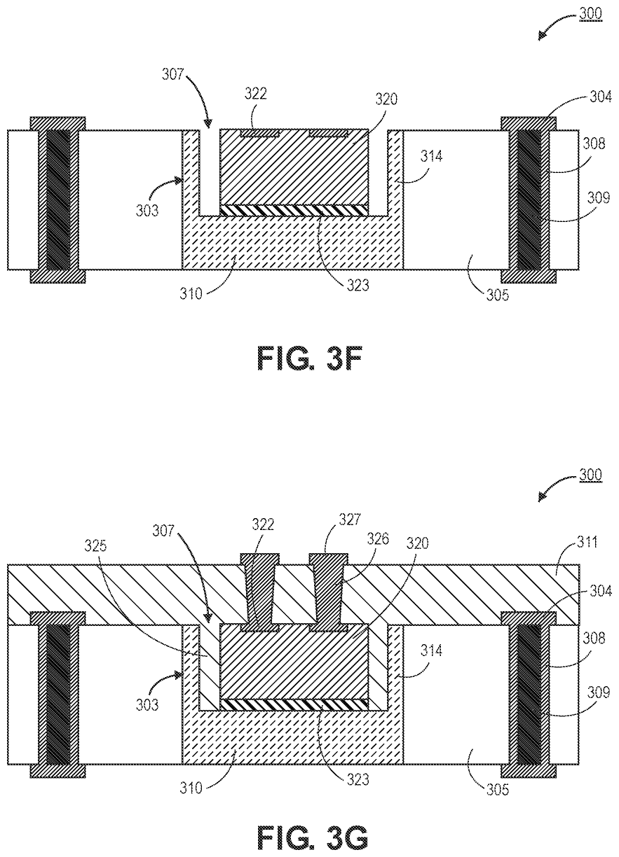

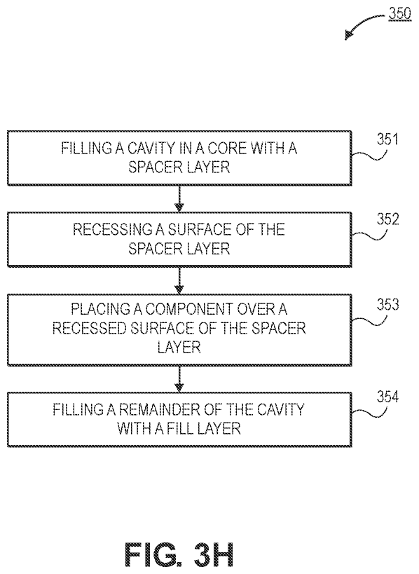

Referring now to FIGS. 3A-3G, a series of cross-sectional illustrations depicting a process for assembling a package substrate 300 with a component 320 embedded in a core 305 is shown, in accordance with an embodiment. In the embodiment shown in FIGS. 3A-3G, a spacer layer 310 is fabricated at a bottom of cavity 307 through the core 305, and the component 320 is placed on the spacer layer 310.

Referring now to FIG. 3A, a cross-sectional illustration of a portion of a package substrate 300 is shown, in accordance with an embodiment. In an embodiment, the package substrate 300 may comprises a core 305. The core 305 may be an organic core 305, a glass core 305, or the like. The core 305 may be similar to any of the cores described in greater detail herein.

In an embodiment, a via 308 may pass through a thickness of the core 305. The via 308 may comprise electrically conductive material, such as copper or the like. In the illustrated embodiment, the vias 308 have a plated through hole (PTH) configuration. That is, the vias 308 comprise an electrically conductive shell that is filled with an insulating plug 309. In other embodiments, the vias 308 may be fully filled with electrically conductive material. Further, the vias 308 may have any suitable cross-sectional shape. For example, vias 308 may have vertical sidewalls (as shown in FIG. 3A), tapered sidewalls, or the like. Electrically conductive pads 304 may be provided over and/or under the vias 308.

Referring now to FIG. 3B, a cross-sectional illustration of the portion of the package substrate 300 after a cavity 307 is formed through the core 305 is shown, in accordance with an embodiment. In an embodiment, the cavity 307 may be formed with any suitable subtractive process. For example, a drilling process, a laser ablation process, an etching process, or the like may be used to form the cavity 307. Sidewalls 303 of the cavity 307 may be substantially orthogonal to the top and bottom surfaces of the core 305. In other embodiments, the sidewalls 303 may be sloped, curved, or have any suitable profile.

Referring now to FIG. 3C, a cross-sectional illustration of the portion of the package substrate 300 after a carrier 306 is applied across a bottom of the core 305 is shown, in accordance with an embodiment. In an embodiment, the carrier 306 may span a bottom opening of the cavity 307. The carrier 306 provides a surface at the bottom of the cavity 307 on which subsequent layers and components may be supported. In an embodiment, the carrier 306 may be any suitable substrate material (e.g., glass, ceramic, metal, etc.) or a tape. In some instances, a temporary release film (not shown) may be provided between the carrier 306 and the core 305. This allows for subsequent removal of the carrier 306 (e.g., through thermal processes, laser processes, etc.).

Referring now to FIG. 3D, a cross-sectional illustration of the portion of the package substrate 300 after a spacer layer 310 is disposed in the cavity 307 is shown, in accordance with an embodiment. The spacer layer 310 may be a dielectric material, such as an organic buildup film, a molding material, an epoxy, a PID, or the like. In an embodiment, the spacer layer 310 may substantially fill the cavity 307. The spacer layer 310 may be disposed in the cavity 307 with a lamination process, a molding process, ink injection process, or any other suitable process. In some embodiments, a planarization process, an etching process, or the like may be used to make the spacer layer 310 planar with a surface of the core 305.

Referring now to FIG. 3E, a cross-sectional illustration of the portion of the package substrate 300 after a surface 312 of the spacer layer 310 is recessed is shown, in accordance with an embodiment. In an embodiment, the surface 312 may be recessed with any suitable subtractive process, such as milling, laser ablation, etching (wet or dry), or the like. In an embodiment, the surface 312 may have a width that is smaller than a total width of the spacer layer 310. As such, arms 314 may be formed along the sidewalls 303 of the cavity 307. The arms 314 may have top surfaces that are substantially coplanar with a top surface of the core 305.

Referring now to FIG. 3F, a cross-sectional illustration of the portion of the package substrate 300 after the carrier 306 is removed and a component 320 with pads 322 is inserted into the cavity 307 is shown, in accordance with an embodiment. In an embodiment, the component 320 may be coupled to the spacer layer 310 by an intervening layer 323, such as a DBF or the like. The component 320 may be similar to any of the components described in greater detail herein. For example, the component 320 may comprise passive electrical devices, such as one or more of an inductor, a capacitor, or a resistor. In an embodiment, a width of the component 320 is smaller than a width of the spacer layer 310. For example, a gap may be provided between the arms 314 and the component 320 in some embodiments.

Referring now to FIG. 3G, a cross-sectional illustration of the portion of the package substrate 300 after a buildup layer 311 and fill layer 325 are applied is shown, in accordance with an embodiment. In an embodiment, the fill layer 325 may fill the gaps between the component 320 and the arms 314. The fill layer 325 may be the same material as the buildup layer 311. For example, the fill layer 325 and the buildup layers 311 may comprise organic dielectric material, such as buildup film or the like. In an embodiment, vias 326 may be provided through the buildup layer 311 in order to couple pads 327 to the pads 322 on the component 320.

Referring now to FIG. 3H, a process flow diagram of a process 350 for embedding a component in a core is shown, in accordance with an embodiment. In an embodiment, the process 350 may begin with operation 351, which comprises filling a cavity in a core with a spacer layer. The operation 351 may include structures and processes similar to those described herein with respect to one or more of FIGS. 3A-3D.

In an embodiment, the process 350 may continue with operation 352, which comprises recessing a surface of the spacer layer. The operation 352 may include structures and processes similar to those described herein with respect to FIG. 3E.

In an embodiment, the process 350 may continue with operation 353, which comprises placing a component over a recessed surface of the spacer layer. The operation 353 may include structures and processes similar to those described herein with respect to FIG. 3F.

In an embodiment, the process 350 may continue with operation 354, which comprises filling a remainder of the cavity with a fill layer. The operation 354 may include structures and processes similar to those described herein with respect to FIG. 3G.

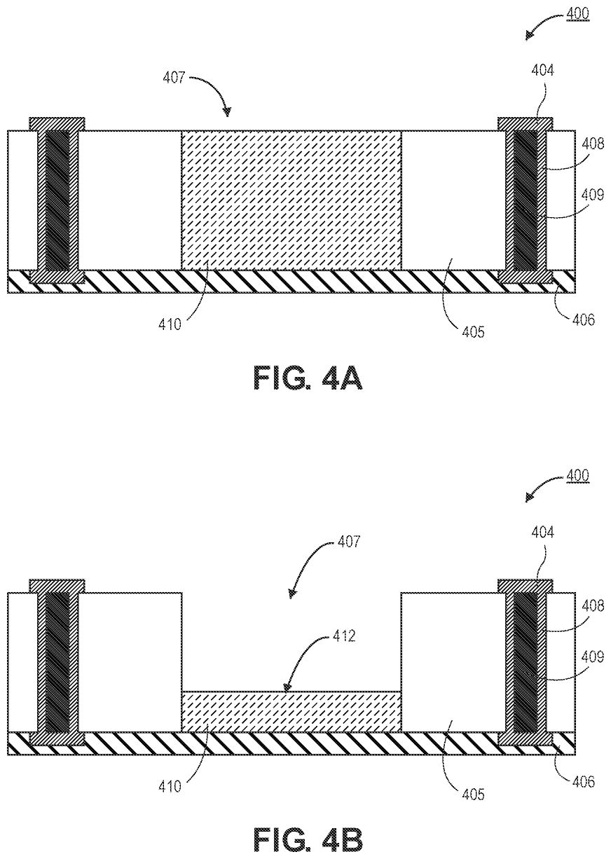

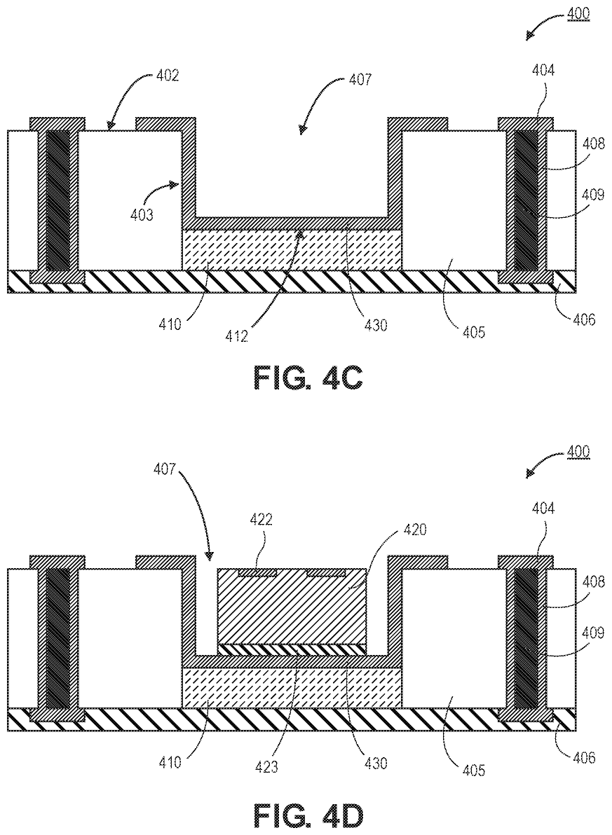

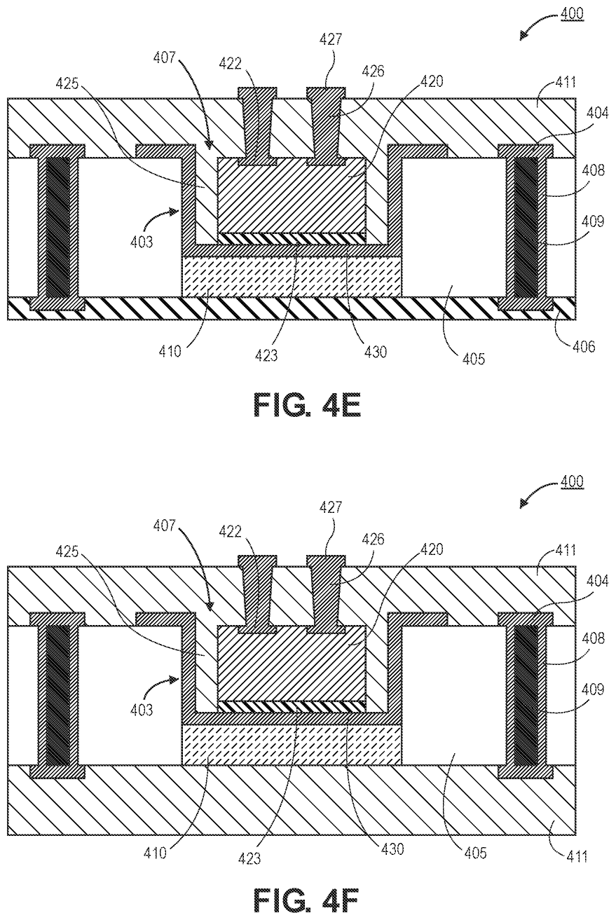

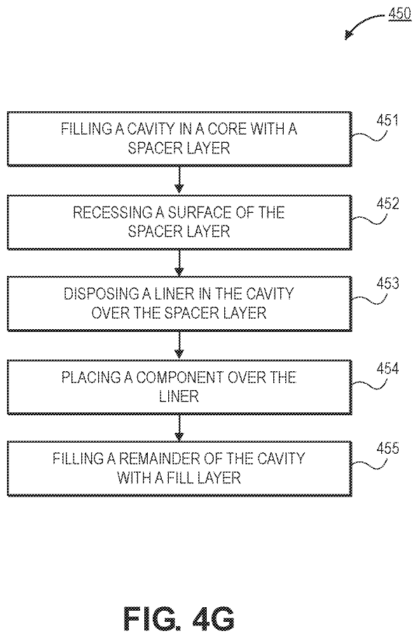

Referring now to FIGS. 4A-4F, a series of cross-sectional illustrations depicting a process for assembling a package substrate 400 with a component 420 embedded in a core 405 is shown, in accordance with an embodiment. In the embodiment shown in FIGS. 4A-4F, a spacer layer 410 is fabricated at a bottom of cavity 407 through the core 405, and a liner 430 is applied over the spacer layer 410. A component 420 is placed on the liner 430.

Referring now to FIG. 4A, a cross-sectional illustration of a portion of a package substrate 400 is shown, in accordance with an embodiment. In an embodiment, the package substrate 400 may comprise a core 405, such as a glass core 405, an organic core 405, or the like. The core 405 may be similar to any of the cores described in greater detail herein. In an embodiment, vias 408 (with or without plugs 409) may be provided between pads 404 at the top and bottom of the core 405.

In an embodiment, a spacer layer 410 may fill a cavity 407 that passes through a thickness of the core 405. The spacer layer 410 may comprise a dielectric material, such as an organic buildup film, a molding material, an epoxy, a PID, or the like. In an embodiment, a carrier 406 or tape is provided at a bottom of the core 405 in order to provide a support surface for the spacer layer 410.

Referring now to FIG. 4B, a cross-sectional illustration of the portion of the package substrate 400 after the spacer layer 410 is recessed is shown, in accordance with an embodiment. In an embodiment, the spacer layer 410 may be recessed so that surface 412 is below a top surface of the core 405. In an embodiment, the spacer layer 410 may be recessed with an etching process, a drilling process, a laser ablation process, or the like. In the illustrated embodiment, the surface 412 of the spacer layer 410 extends across the entire width of the spacer layer 410. Though, in other embodiments arm structures (similar to those described above) may also be provided on the spacer layer 410.

Referring now to FIG. 4C, a cross-sectional illustration of the portion of the package substrate 400 after a liner 430 is formed, is shown, in accordance with an embodiment. In an embodiment, the liner 430 may be provided over the surface 412 of the spacer layer 410 and sidewalls 403 of the cavity 407. The liner 430 may also cover a portion of the top surface 402 of the core 405. In an embodiment, the liner 430 comprises a metallic material, such as copper. The liner 430 may be plated with an electroplating process, or the like. In such instances, a seed layer (not shown) may be provided below the liner 430. The use of a plating process allows for precise control of the thickness of the liner 430. As such, an accurate combined thickness of the spacer layer 410 and the liner 430 can be produced in order to set the proper height for the subsequently added component 420.

Referring now to FIG. 4D, a cross-sectional illustration of the portion of the package substrate 400 after the component 420 is inserted into the cavity 407 is shown, in accordance with an embodiment. In an embodiment, the component 420 may be a passive electrical device, such as one comprising one or more of an inductor, a capacitor, or a resistor. The component 420 may be similar to any of the components described in greater detail herein. In an embodiment, the component 420 may include pads 422. The component 420 may have a width that is narrower than a width of the cavity 407. In some instances, a gap is provided between a sidewall of the component 420 and the liner 430.

In an embodiment, an intervening layer 423 couples the component 420 to the liner 430. The intervening layer 423 may be an adhesive, such as a DBF. In other embodiments, the intervening layer 423 may comprise solder. For example, a backside of the component 420 may be metallized in some instances to accommodate the use of solder. Solder and metallization may improve thermal control of the component 420 since thermal energy can be more effectively withdrawn from the component 420 and dissipated by the liner 430.

Referring now to FIG. 4E, a cross-sectional illustration of the portion of the package substrate 400 after a fill layer 425 and buildup layer 411 are added over the core 405 is shown, in accordance with an embodiment. In an embodiment, the fill layer 425 may be provided in the cavity 407 between the liner 430 and the component 420. The fill layer 425 may be the same material or a similar material as the buildup layer 411. For example, the fill layer 425 and the buildup layer 411 may include organic buildup film or the like. Though, the fill layer 425 may be a different material than the buildup layer 411 in other embodiments.

Referring now to FIG. 4F, a cross-sectional illustration of the portion of the package substrate 400 after the carrier 406 is removed and a buildup layer 411 is applied under the core 405 is shown, in accordance with an embodiment. The buildup layer 411 may be applied with a lamination process or the like. Additional electrical routing (e.g., pads, vias, traces, etc.) (not shown) may also be provided in and/or on the buildup layer 411.

Referring now to FIG. 4G, a process flow diagram of a process 450 for embedding a component in a core is shown, in accordance with an embodiment. In an embodiment, the process 450 may begin with operation 451, which comprises filling a cavity in a core with a spacer layer. The operation 451 may include structures and processes similar to those described herein with respect to FIG. 4A.

In an embodiment, the process 450 may continue with operation 452, which comprises recessing a surface of the spacer layer. The operation 452 may include structures and processes similar to those described herein with respect to FIG. 4B.

In an embodiment, the process 450 may continue with operation 453, which comprises disposing a liner in the cavity over the spacer layer. The operation 453 may include structures and processes similar to those described herein with respect to FIG. 4C.

In an embodiment, the process 450 may continue with operation 454, which comprises placing a component over the liner. The operation 454 may include structures and processes similar to those described herein with respect to FIG. 4D.

In an embodiment, the process 450 may continue with operation 455, which comprises filling a remainder of the cavity with a fill layer. The operation 455 may include structures and processes similar to those described herein with respect to one or both of FIG. 4E and FIG. 4F.

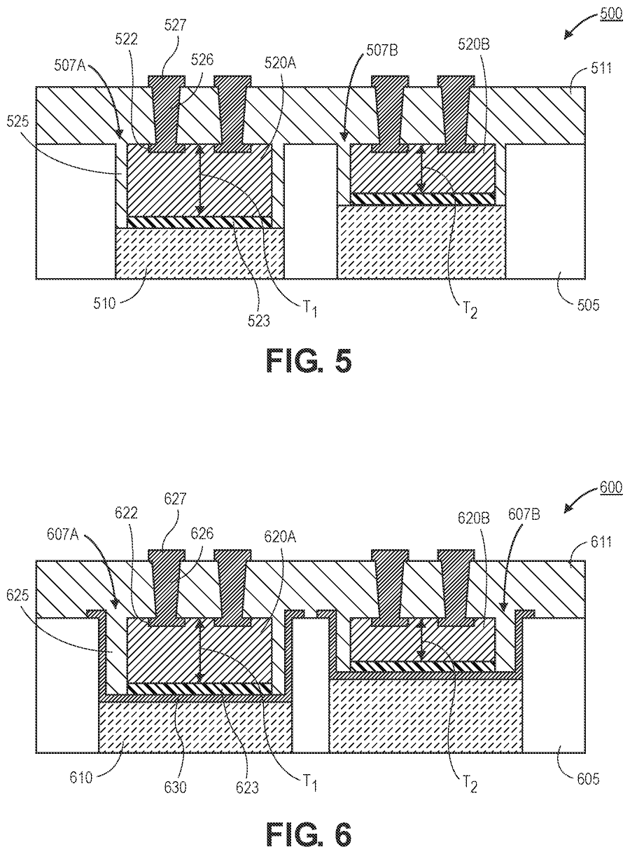

Referring now to FIG. 5, a cross-sectional illustration of a portion of a package substrate 500 is shown, in accordance with an embodiment. In an embodiment, the package substrate 500 comprises a core 505. The core 505 may be an organic core 505, a glass core 505, or the like. The core 505 may be similar to any of the cores described in greater detail herein. In an embodiment, a plurality of cavities 507 may be provided through a thickness of the core 505. For example, a first cavity 507A and a second cavity 507B may be provided through the core 505.

In an embodiment, a first component 520A may be provided in the first cavity 507A, and a second component 520B may be provided in the second cavity 507B. While a single component 520 is provided in each cavity 507, it is to be appreciated that the cavities 507A and/or 507B may be sized to accommodate a plurality of components 520. For example, two or more components 520 may be inserted into the first cavity 507A in some embodiments. The components 520A and 520B may be similar to any of the components described in greater detail herein. For example, the components 520A and 520B may comprise one or more of an inductor, a capacitor, or a resistor. The components 520A and 520B may be coupled to the spacer layers 510 by intervening layers 523, such as an adhesive. Fill layers 525 may fill the remainder of the cavities 507, and buildup layer 511 may be provided over the core 505. Pads 527 and vias 526 may be coupled to pads 522 on the top surfaces of the components 520A and 520B.

In an embodiment, the components 520A and 520B may have different thicknesses. For example, the first component 520A may have a first thickness T₁, and the second component 520B may have a second thickness T₂ that is smaller than the first thickness T₁. In order to maintain uniform heights of the top surfaces of the two components 520A and 520B, the spacer layers 510 may have different thicknesses as well. Accordingly, different types of components 520 (e.g., with different functionalities, different dimensions, different capacities, etc.) may be integrated into the same package substrate 500.

Referring now to FIG. 6, a cross-sectional illustration of a portion of a package substrate 600 is shown, in accordance with an additional embodiment. In an embodiment, the package substrate 600 comprises a core 605. The core 605 may be an organic core 605, a glass core 605, or the like. The core 605 may be similar to any of the cores described in greater detail herein. In an embodiment, a plurality of cavities 607 may be provided through a thickness of the core 605. For example, a first cavity 607A and a second cavity 607B may be provided through the core 605.

In an embodiment, each cavity 607A and 607B may be at least partially filled with a spacer layer 610 and a liner 630. The components 620A and 620B may be coupled to the liner 630 by an intermediate layer 623 (e.g., an adhesive or a solder). Fill layers 625 may fill the remainder of the cavities 607, and buildup layer 611 may be provided over the core 605. Pads 627 and vias 626 may be coupled to pads 622 on the top surfaces of the components 620A and 620B.

In an embodiment, the components 620A and 620B may have different thicknesses. For example, the first component 620A may have a first thickness T₁, and the second component 620B may have a second thickness T₂ that is smaller than the first thickness T₁. In order to maintain uniform heights of the top surfaces of the two components 620A and 620B, the spacer layers 610 may have different thicknesses as well. Accordingly, different types of components 620 (e.g., with different functionalities, different dimensions, different capacities, etc.) may be integrated into the same package substrate 600.

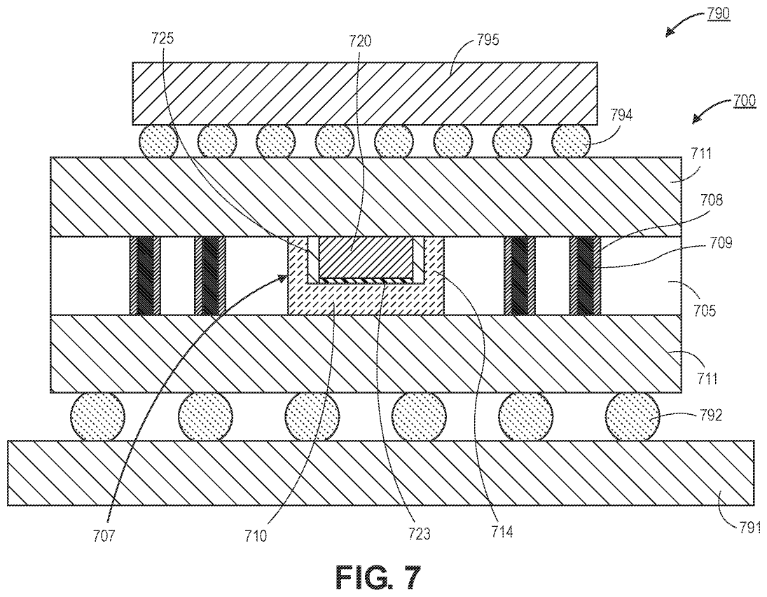

Referring now to FIG. 7, a cross-sectional illustration of an electronic system 790 is shown, in accordance with an embodiment. In an embodiment, the electronic system 790 comprises a board, such as a printed circuit board (PCB), a motherboard, or the like. In an embodiment, the board 791 is coupled to a package substrate 700 by interconnects 792. The interconnects 792 may be second level interconnects (SLIs), such as solder balls, sockets, pins, or the like.

In an embodiment, the package substrate 700 may be similar to any of the package substrates described herein. For example, the package substrate 700 may include a core 705 (e.g., a glass core 705 or an organic core 705) with buildup layers 711 above and below the core 705. The core 705 may comprise vias 708. In FIG. 7, the vias 708 are filled with an insulating plug 709. A cavity 707 may be provided through a thickness of the core 705.

In an embodiment, a component 720 may be set into the cavity 707. For example, the component 720 may be supported by a spacer layer 710 within the cavity 707. The spacer layer 710 may comprise arms 714 that extend up to a top surface of the core 705. In some embodiments, a liner (not shown) may also be provided over the spacer layer 710. In an embodiment, an intervening layer 723 may couple the component 720 to the spacer layer 710. The spacer layer 710 may comprise a dielectric material, such as an organic buildup film, a molding material, an epoxy, a PID, or the like. A fill layer 725 surrounds the component 720 and fills a remaining portion of the cavity 707.

In an embodiment, one or more dies 795 may be coupled to the package substrate 700 by interconnects 794. The interconnects 794 may comprise first level interconnects (FLIs), such as solder balls, copper bumps, hybrid bonding interfaces, or the like. The die 795 may be any type of die, such as a central processing unit (CPU), a graphics processing unit (GPU), an XPU, a communications die, a memory die, an application specific integrated circuit (ASIC), a field programmable gate array (FPGA), or the like. In an embodiment, the component 720 is electrically coupled to the one or more dies 795 in order to control and/or improve power delivery that is provided to the die 795.

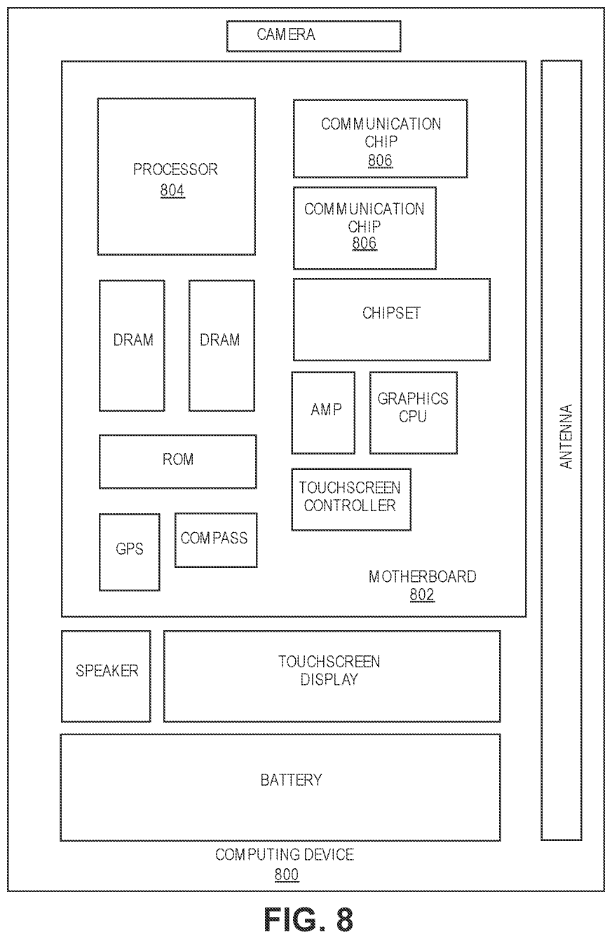

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a core with a cavity, and a passive electrical component is supported by a spacer layer within the cavity, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes core with a cavity, and a passive electrical component is supported by a spacer layer within the cavity, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with a first surface and a second surface opposite from the first surface; a cavity through a thickness of the substrate; a first layer in the cavity, wherein the first layer has a first width; a component on the first layer, wherein the component has a second width that is smaller than the first width; and a second layer between a sidewall of the cavity and a sidewall of the component.

Example 2: the apparatus of Example 1, wherein the first layer is a dielectric material.

Example 3: the apparatus of Example 1 or Example 2, wherein the first layer comprises: an arm that extends up from an edge of the first layer, and wherein a top surface of the arm is substantially coplanar with the second surface of the substrate.

Example 4: the apparatus of Example 3, wherein the arm is between the second layer and the sidewall of the cavity.

Example 5: the apparatus of Examples 1-4, further comprising: a liner in the cavity, wherein the liner contacts the sidewall of the cavity and a surface of the first layer.

Example 6: the apparatus of Example 5, wherein the liner covers a portion of the second surface of the substrate.

Example 7: the apparatus of Example 5 or Example 6, wherein the liner comprises copper.

Example 8: the apparatus of Examples 1-7, wherein the first layer has a different material composition than the second layer.

Example 9: the apparatus of Examples 1-8, wherein sidewalls of the cavity are substantially orthogonal to the first surface of the substrate.

Example 10: the apparatus of Examples 1-9, wherein the substrate comprises an organic dielectric or a glass layer with a rectangular prism form factor.

Example 11: an apparatus, comprising: a substrate; a cavity through a thickness of the substrate, wherein the cavity has a first width; a first layer in the cavity, wherein the first layer has the first width and seals an opening of the cavity; a component coupled to the first layer, wherein a first distance from a bottom of the first layer to a top of the component is substantially equal to a second distance from a bottom surface of the substrate to a top surface of the substrate; and a second layer in the cavity between the component and a sidewall of the cavity.

Example 12: the apparatus of Example 11, wherein the first layer comprises a dielectric material.

Example 13: the apparatus of Example 12, wherein the first layer comprises a photoimageable dielectric (PID).

Example 14: the apparatus of Examples 11-13, wherein the first layer further comprises: arms that extend up to the top surface of the substrate.

Example 15: the apparatus of Examples 11-14, further comprising: an intermediate layer between the first layer and the component.

Example 16: the apparatus of Examples 11-15, further comprising: a liner along sidewalls of the cavity and over a surface of the first layer.

Example 17: an apparatus, comprising: a board; a package substrate coupled to the board, wherein the package substrate comprises: a core; a cavity through a thickness in the core; a spacer at a bottom of the cavity, wherein the spacer has a surface that is substantially parallel to a top surface of the core; a component over the spacer and within the cavity, wherein a top surface of the component is substantially coplanar with the top surface of the core; and a fill layer around the component within the cavity; and a die coupled to the package substrate.

Example 18: the apparatus of Example 17, wherein the spacer comprises arms that extend to the top surface of the core, wherein the arms contact sidewalls of the cavity.

Example 19: the apparatus of Example 17 or Example 18, further comprising: a liner within the cavity, wherein the liner contacts sidewalls of the cavity and a surface of the spacer.

Example 20: the apparatus of Examples 17-19, wherein the apparatus is part of a personal computer, a server, a mobile device, a tablet, or an automobile.

What is claimed is:

1. An apparatus, comprising:
a substrate with a first surface and a second surface opposite from the first surface;
a cavity through a thickness of the substrate;
a first layer in the cavity, wherein the first layer has a first width;
a component on the first layer, wherein the component has a second width that is smaller than the first width; and
a second layer between a sidewall of the cavity and a sidewall of the component.

2. The apparatus of claim 1, wherein the first layer is a dielectric material.

3. The apparatus of claim 1, wherein the first layer comprises:
an arm that extends up from an edge of the first layer, and wherein a top surface of the arm is substantially coplanar with the second surface of the substrate.

4. The apparatus of claim 3, wherein the arm is between the second layer and the sidewall of the cavity.

5. The apparatus of claim 1, further comprising:
a liner in the cavity, wherein the liner contacts the sidewall of the cavity and a surface of the first layer.

6. The apparatus of claim 5, wherein the liner covers a portion of the second surface of the substrate.

7. The apparatus of claim 5, wherein the liner comprises copper.

8. The apparatus of claim 1, wherein the first layer has a different material composition than the second layer.

9. The apparatus of claim 1, wherein sidewalls of the cavity are substantially orthogonal to the first surface of the substrate.

10. The apparatus of claim 1, wherein the substrate comprises an organic dielectric or a glass layer with a rectangular prism form factor.

11. An apparatus, comprising:
a substrate;
a cavity through a thickness of the substrate, wherein the cavity has a first width;
a first layer in the cavity, wherein the first layer has the first width and seals an opening of the cavity;
a component coupled to the first layer, wherein a first distance from a bottom of the first layer to a top of the component is substantially equal to a second distance from a bottom surface of the substrate to a top surface of the substrate; and
a second layer in the cavity between the component and a sidewall of the cavity.

12. The apparatus of claim 11, wherein the first layer comprises a dielectric material.

13. The apparatus of claim 12, wherein the first layer comprises a photoimageable dielectric (PID).

14. The apparatus of claim 11, wherein the first layer further comprises:
arms that extend up to the top surface of the substrate.

15. The apparatus of claim 11, further comprising:
an intermediate layer between the first layer and the component.

16. The apparatus of claim 11, further comprising:
a liner along sidewalls of the cavity and over a surface of the first layer.

17. An apparatus, comprising:
a board;
a package substrate coupled to the board, wherein the package substrate comprises:
a core;
a cavity through a thickness in the core;
a spacer at a bottom of the cavity, wherein the spacer has a surface that is substantially parallel to a top surface of the core;
a component over the spacer and within the cavity, wherein a top surface of the component is substantially coplanar with the top surface of the core; and
a fill layer around the component within the cavity; and
a die coupled to the package substrate.

18. The apparatus of claim 17, wherein the spacer comprises arms that extend to the top surface of the core, wherein the arms contact sidewalls of the cavity.

19. The apparatus of claim 17, further comprising:
a liner within the cavity, wherein the liner contacts sidewalls of the cavity and a surface of the spacer.

20. The apparatus of claim 17, wherein the apparatus is part of a personal computer, a server, a mobile device, a tablet, or an automobile.
